(19) United States
(12) Patent Application Publication
(10) Pub. No.: US 2013/0017649 A1
(43) Pub. Date: Jan. 17, 2013

(54) PACKAGING FOR CLIP-ASSEMBLED ELECTRONIC COMPONENTS

(71) Applicants: Dominique Touzet, Savigne Sous le Lude (FR); Pascal Coirault, Ballan-Mire (FR)

(72) Inventors: Dominique Touzet, Savigne Sous le Lude (FR); Pascal Coirault, Ballan-Mire (FR)

(73) Assignee: STMicroelectronics (Tours) SAS, Tours (FR)

(21) Appl. No.: 13/510,598

(22) PCT Filed: Oct. 29, 2010
(86) PCT No.: PCT/FR10/52329

§ 371 Date: Sep. 27, 2012

(30) Foreign Application Priority Data
Nov. 25, 2009 (FR) 0958349

(51) Int. Cl. H01L 21/60; B23P 19/00; H01L 23/495

(52) U.S. Cl. 438/112; 257/676; 29/740; 257/E21.506; 257/E23.031

(57) ABSTRACT

A system for assembling electronic chips in a package, including a first lead frame defining chip reception areas; and a second lead frame defining chip coverage areas, the frames including, at least at their periphery, pairs of mutually-cooperating elements for maintaining the frames together.

### CROSS REFERENCE TO RELATED APPLICATIONS

This application is a U.S. National Stage patent application based on International patent application number PCT/FR2010/052329, filed on Oct. 29, 2010, which application claims the priority benefit of French patent application number 09/58349, filed on Nov. 25, 2009, which applications are hereby incorporated by reference to the maximum extent allowable by law.

### BACKGROUND

1. Technical Field

The present invention generally relates to electronic circuits and, more specifically, to the assembly of electronic chips in a package. The present invention more specifically relates to so-called clip packages in which, during their assembly, semiconductor chips having contacts on both surfaces are tightened between two conductive plates, each provided with pins of contact transfer on a same plane.

2. Discussion of the Related Art

Among the great number of techniques of semiconductor component packaging assembly, the so-called clip assembly is specifically adapted to chips having a small number of contacts.

FIGS. 1A and 1B are respective lateral and front views of an electronic device 1 assembled in a so-called clip SMD package (Surface Mount Device). A semiconductor chip 12 forming, for example, a vertical device (for example, a diode or a power thyristor) or an integrated circuit with a small number of contacts (typically from two to four) is assembled on a reception area 142 pertaining to a base 14, this area having a surface area greater than the surface area of chip 12. Plate 142 extends outside of the package in at least one coplanar pin 144 of connection to the outside. A cap 16, called a clip, is placed on the upper surface of chip 12 and is shaped to define at least one pin 164 of connection to the outside of the package in the plane of base 14. A chip coverage area 162 is connected to pin(s) 164 by a curved portion 166. In the example of FIG. 1B, the package is assumed to comprise a single connection pin 144 on the base side and a single connection pin 164 on the cap side.

Bases 14 and caps 16 are made of a conductive material, most often copper. In the case of a package having one of its elements, base or cap, comprising more than one conductive pin, an insulating region (for example, made of ceramic) is provided on area 142 or 162 to dissociate the contacts. Chip 12 comprises contacts on both its surfaces, which are transferred to areas 142 and 162 of base 14 and of cap 16 by soldering or welding 18 (FIG. 1B). Most often, the assembly is encapsulated in an insulating resin 10 (illustrated by dotted lines in FIG. 1A).

Packages such as illustrated in FIGS. 1A and 1B are obtained in batches from lead to frames comprising a large number of temporarily interconnected supports and of caps.

FIG. 2 is a perspective view of an example of a conventional system for assembling chips in packages of devices 1 such as illustrated in FIGS. 1A and 1B,

An assembly frame 22 receives a first lead frame 24 comprising supports 14 connected to one another. Then, chips 12 (not shown in FIG. 2) are deposited on plates 142 of supports 14 with an interposed solder layer. Then, a second lead frame 26 comprising caps 16 is placed on the assembly with, here again, an interposed solder layer. The positioning of frames 24 and 26 with respect to each other is performed by slugs 222 protruding from frame 22 and engaged into corresponding openings of frames 24 and 26. The assembly is held by gravity.

The assembly is submitted to a thermal processing to weld the chip contacts.

The upper portion of the assembly may be placed in a mold to embed the different circuits in an epoxy resin.

Finally, the circuits are individualized by cutting of their pins 144 and 164 (FIGS. 1A and 1B) of connection of frames 24 and 26, to obtain encapsulated electronic devices 1.

The use of a handling frame 22 generates a disadvantage linked to the thermal mass of the entire assembly system. This thermal mass increases the manufacturing cost. Further, an inhomogeneity appears in the thermal gradients between the periphery and the center.

Further, the fact for the assembly to only be held by gravity generates a risk of displacement during manipulations with a thermal processing, or even of deformation of the lead frames in the vertical direction in their central portions which do not rest on the frame. This adversely affects the quality of the assembly.

### SUMMARY

An object of an embodiment of the present invention is to overcome all or part of the disadvantages of usual systems of clip assembly of electronic devices.

Another object of an embodiment of the present invention more specifically aims at avoiding problems due to the thermal mass of the usual support frame.

An object of an embodiment of the present invention is to improve the evenness of the assembly.

To achieve all or part of these objects as well as others, the present invention provides a system for assembling electronic chips in a package, comprising a first lead frame defining chip reception areas; and a second lead frame defining chip coverage areas, the frames comprising, at least at their periphery, pairs of mutually-cooperating elements for maintaining the frames together.

According to an embodiment of the present invention, each pair of elements comprises a pin protruding from one of the frames and an opposite opening in the other frame.

According to an embodiment of the present invention, the assembly of the lead frames by said elements is of clip type.

According to an embodiment of the present invention, mutually-cooperating elements are regularly distributed in the lead frames.

According to an embodiment of the present invention, said elements take part in the alignment of the lead frames with respect to each other.

According to an embodiment of the present invention, the reception and coverage areas are continued by pins intended to form contact pins.

The present invention also provide a method for packaging electronic chips by means of a system such as hereabove, comprising the steps of:

arranging electronic chips on said reception areas, with an interposed solder layer;

arranging the second connection frame on the first one with an interposed second solder layer;

submitting the assembly to a thermal processing; and

scribing the obtained packages.

According to an embodiment of the present invention, the chips are encapsulated before scribing of the lead frames.

The present invention also provides a lead frame of a conductive material defining semiconductor chip reception areas of a system such as hereabove, comprising square or rectangular openings intended to receive pins protruding from the second lead frame defining caps covering the chips.

The present invention also provides a lead frame of a conductive material of a system defining caps for covering semiconductor chips supported by areas for receiving the first lead frame, comprising pins protruding from a surface and intended to cooperate with the first lead frame.

The foregoing objects, features, and advantages of the present invention will be to discussed in detail in the following non-limiting description of specific embodiments in connection with the accompanying drawings.

### BRIEF DESCRIPTION OF THE DRAWINGS

FIGS. 1A and 1B, previously described, are lateral and top views of an example of an electronic device of the type to which the present invention applies;

FIG. 2, previously described, is a perspective view of a usual system for assembling chips in a clip package;

FIG. 3 is a partial perspective view of an embodiment of a lead frame supporting caps;

FIG. 3A is a partial cross-section view of the frame of FIG. 3 along line A-A;

FIG. 4 is a partial perspective view of an embodiment of a lead frame supporting chip supports;

FIG. 5 is a partial perspective view of the assembly of the frames of FIGS. 3 and 4; and

FIG. 6 is a partial lateral cross-section view of the assembly of FIG. 5.

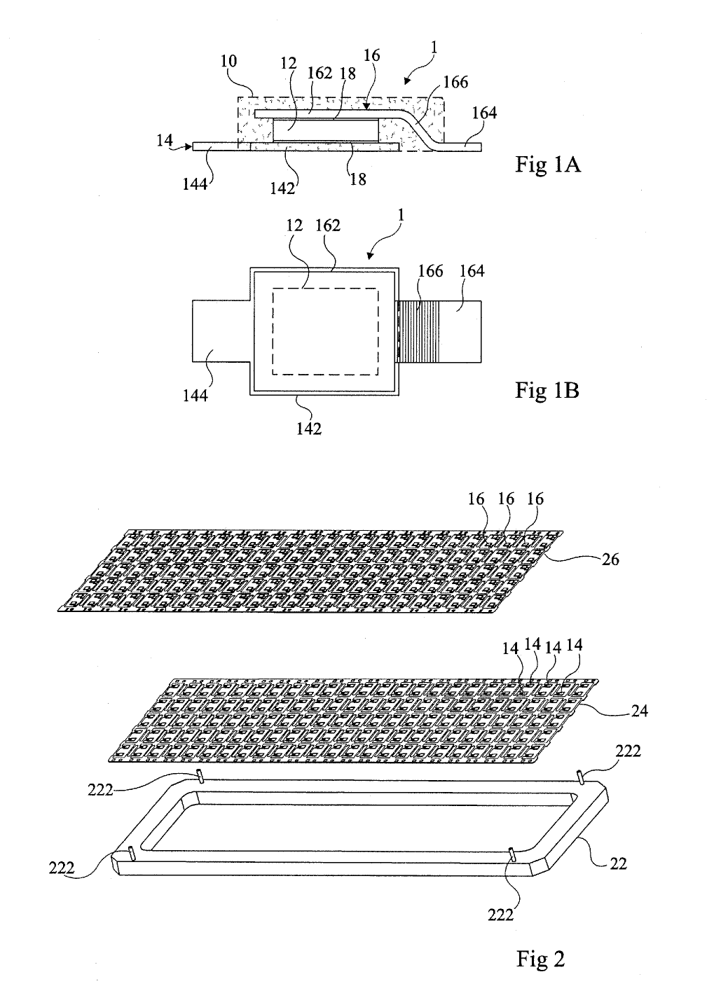

### DETAILED DESCRIPTION

The same elements have been designated with the same reference numerals in the different drawings. For clarity, only those elements and steps which are useful to the understanding of the present invention have been shown and will be described. In particular, the forming of the semiconductor chips and of their contacts has not been detailed, the present invention being compatible with usual techniques. Further, the soldering and encapsulation operations have not been detailed, the present invention being here again compatible with usual techniques.

It could be devised to improve the hold on frame 22 (FIG. 2) by placing nuts or similar clamping means on slugs 22. However, this would solve neither the problem of thermal mass, nor that of a possible deflection in the central portion.

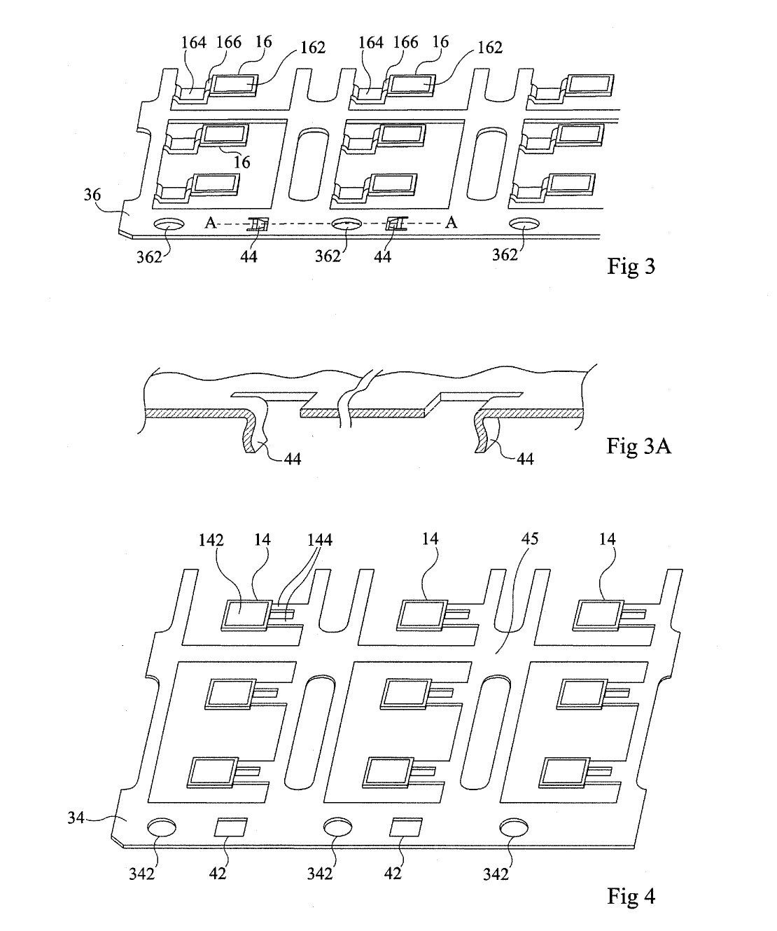

It is provided to avoid using a frame to support and hold together the lead frames to be assembled with interposed semiconductor chips. For this purpose, elements are provided in each lead frame, each of these elements being intended to cooperate, for example, as a clip, to block the respective positions of the two frames with respect to each other. FIG. 3 is a perspective view of an embodiment of a frame portion 36 of caps 16 for covering chips in a “clip”-type package assembly.

FIG. 3A is a cross-section view shown a portion of frame 36 at the level of line A-A of FIG. 3.

FIG. 4 is a perspective view of an embodiment of a frame portion 34 of supports 14 for receiving chips. For simplification, the chips have not been shown in FIGS. 3 and 4.

Each support 14 comprises, as previously, an area 142 for receiving a chip and one or several pins 144 intended to transfer chip contacts to the outside (two pins in the example of FIG. 4).

Each cap 16 comprises, as previously, an area 162 for covering the chip and one or several contact transfer pins 164 connected to area 162 by one or several curved connection portions 166 (a single portion in the example of FIG. 3).

Lead frames 34 and 36 comprise, at their periphery, mutually-cooperating elements for holding the frames together.

For example, frame 34 comprises openings 42 intended to cooperate with clip-shaped pins 44 made opposite thereto in gate 36. The clips are for example obtained by stamping, similarly to the way in which the different caps 16 are obtained. In the example of FIG. 3A, clips 44 have a folded curved shaped to improve the hold. Preferably, and as illustrated in FIG. 3A, clips of different orientations are provided to properly align frames 34 and 36 with respect to each other.

FIGS. 3 and 4 further show circular openings 362 and 342. Such openings are usual and are intended for the step-by-step indexing of machines for placing the chips.

As a variation, clips may be provided on the side of frames 34 and 36 and openings may be provided opposite thereto in the other frame. However, clips on a single lead frame are sufficient.

The shape of openings 42 may, instead of being square or rectangular, as shown, rather be oblong, while preferably having linear edges capable of cooperating with pins 44 to clamp the frame together. Further, the tip of pins 44 may be beveled to be easier to introduce into openings 42. The use of square or rectangular clips prevents the rotation of a frame with respect to the other.

Frames 34 and 36 are obtained by stamping and scribing and require no machining.

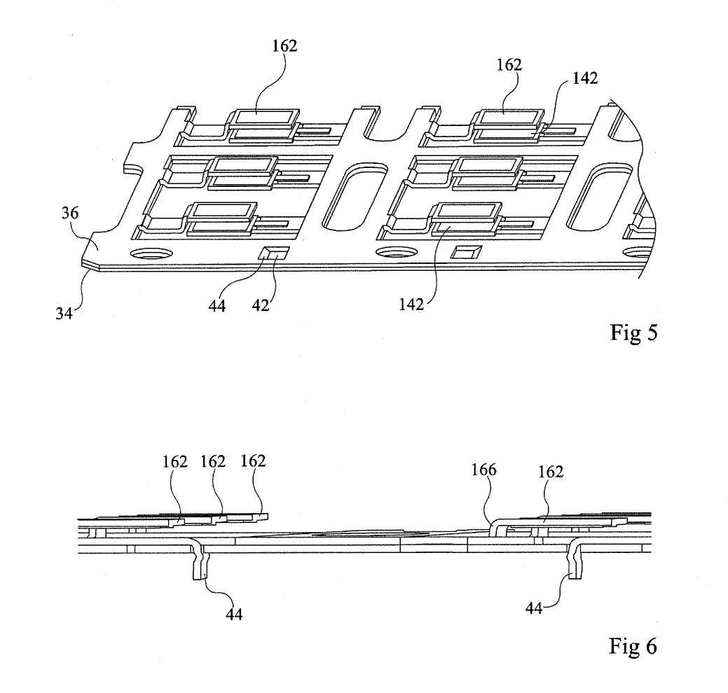

FIG. 5 is a partial perspective view of assembled lead frames 34 and 36.

FIG. 6 is a partial cross-section view of the obtained assembly.

For simplification, the chips and the corresponding solder areas have not been illustrated in FIGS. 5 and 6.

As a specific embodiment, the interval between the supports and the caps is of a few tenths of a millimeter (for example, between 0.2 and 0.4 millimeter).

An advantage of the described embodiment is that the mounting assembly may be manipulated until the scribing without requiring any support frame. Accordingly, there is no further thermal mass problem linked to this frame.

Further, the balance of the assembly system weight is improved.

Further, by a proper distribution of the clips at the periphery of the frames, or even by the provision of clips regularly distributed across the lead frame surface (for example, in central areas 45, FIG. 4), the evenness of the mounting assembly is improved.

Specific embodiments of the present invention have been described, and different variations and modifications will readily occur to those skilled in the art. In particular, the shapes and dimensions to be given to the clips of assembly of the lead frames may vary according to the application. Further, the practical implementation of the present invention based on the functional indications given hereabove is within the abilities of those skilled in the art, using usual techniques for forming lead frames of semiconductor chips as well as usual encapsulation and welding methods.

Such alterations, modifications, and improvements are intended to be within the spirit and scope of the invention. Accordingly, the foregoing description is by way of example only and is not intended as limiting. The invention is limited only as defined in the following claims and the equivalents thereto.

What is claimed is:

1. A system for assembling electronic chips in a package, comprising:
a first lead frame defining chip reception areas; and
a second lead frame defining chip coverage areas,
the frames comprising, at least at their periphery, pairs of mutually-cooperating elements for maintaining the frames together.

2. The system of claim 1, wherein each pair of elements comprises a pin protruding from one of the frames and an opposite opening in the other frame

3. The system of claim 2, wherein the assembly of the lead frames by said elements is of clip type.

4. The system of claim 1, wherein mutually-cooperating elements are regularly distributed in the lead frames.

5. The system of claim 1, wherein said elements take part in the alignment of the lead frames with respect to each other.

6. The system of claim 1, wherein the reception and coverage areas are continued by pins intended to form contact pins.

7. A method for packaging electronic chips in a package, comprising a first lead frame defining chip reception areas; and a second lead frame defining chip coverage areas, the frames comprising, at least at their periphery, pairs of mutually-cooperating elements for maintaining the frames together, comprising the steps of:
arranging electronic chips on said reception areas, with an interposed solder layer
arranging the second connection frame on the first one with an interposed second solder layer;
submitting the assembly to a thermal processing; and
scribing the obtained packages.

8. The method of claim 7, wherein the chips are encapsulated before scribing of the lead frames.

9. A lead frame of a conductive material defining semiconductor chip reception areas of the system of claim 1, comprising square or rectangular openings intended to receive pins protruding from the second lead frame defining caps covering the chips.

10. A lead frame of a conductive material of the system of claim 1, defining caps for covering semiconductor chips supported by areas for receiving the first lead frame, comprising pins protruding from a surface and intended to cooperate with the first lead frame.
